(19) United States
(12) Patent Application Publication
(10) Pub. No.: US 2024/0273592 A1
(43) Pub. Date: Aug. 15, 2024

(54) AUTOMATED PRICE GENERATION IN A CUSTOMIZABLE 3D ENVIRONMENT VISUALIZATION

(71) Applicant: Interior Logic Group Holdings IV, LLC, Irvine, CA (US)

(72) Inventor: Chaitanya KAPADIA, Irvine, CA (US)

(21) Appl. No.: 18/437,151

(22) Filed: Feb. 8, 2024

Related U.S. Application Data
(60) Provisional application No. 63/444,548, filed on Feb. 9, 2023.

(51) Int. Cl. G06Q 30/0601; G06Q 30/0283; G06T 19/00

(52) U.S. Cl. CPC G06Q 30/0621; G06Q 30/0283; G06Q 30/0603; G06Q 30/0643; G06T 19/00; G06T 2200/24; G06T 2210/04

(57) ABSTRACT

A virtual environment customization and pricing system is described that enables a builder to upload a floor plan with information about a room in a building, and a product catalog file specifying information about design options for design elements located in the room. The system is then configured to generate a (“3D”) three-dimensional virtual model representing three-dimensional geometries of a space based on a plurality of three-dimensional images of the space constructed in part from data extracted from builder uploaded files. The homebuyer user may select different design options for the design element causing the system to update the 3D virtual model and total price of the room in accordance with user selections.

### RELATED APPLICATIONS

This application claims the benefit of U.S. Provisional Application No. 63/444,548 filed on Feb. 9, 2023, the contents of which are incorporated herein by reference in their entirety.

### BACKGROUND

Housing inventory shortages and supply-chain issues have strained the construction industry and inflated pricing for many building materials. The ability to limit undesired building material purchases and streamline design decisions to “get it right the first time” provides a significant competitive advantage within the industry.

Conventionally, in a new construction project, buyers utilize design centers in which they can select customization options. The design center may be a brick-and-mortar location showcasing different options that may be selected by the buyer. These options may include various customization options including, for example, stone and tile selections, flooring selections, window selection, paint color selections, fixture selections, and so on. The buyer can review their selections individually or with the assistance of designers and/or the sales staff to complete their customization selections for various projects. Not only this process is arduous, but it also fails to provide buyers with a way to view their selections in their new home, leaving the customer without a clear picture of the final product, i.e., the customization options as applied to the home itself. Finally, the buyer will often be left in the dark as to the cost of the customization until the sales staff reconciles the selections against existing availability and lead time calculations. Moreover, if mistakes are made (e.g., a countertop is purchased in pieces with an undesired seam based on its actual layout in the home and that was unknown to the buyer until the installation), costly and timely repairs and/or repurchases may be required. While some builders utilize visualization programs, they often fail to capture the full scope of the available customizable options and often provide limited views of the space. Moreover, existing visualization applications do not provide real-time product availability and price data.

### SUMMARY

The present disclosure provides systems and methods for effectively pairing visualization of customization selections in a virtual three-dimensional environment with real-time price and availability information to address shortcomings in the industry.

In one aspect of the disclosure, a computer-implement method may include generating a three-dimensional (“3D”) virtual model representing geometries of a space and a plurality of space elements based in part on a plurality of images of the space. In some embodiments, the virtual model is a 3D virtual model. In some embodiments, the images of the space are acquired from multiple disparate aspects to create a three-dimensional image. The computer-implement method may also include obtaining, from a user computing device, a user input specifying a design option for one design element located with the space. The method may furthermore include updating the 3D virtual model by displaying a modified 3D virtual model, wherein the modified 3D virtual model comprises an image of the design element having the specified design option. The method may also include generating an upgrade price for the design element by obtaining pricing data for the design element in the specified design option. The method may also include updating a total price associated with the space based on the generated upgrade price of the design element. Other embodiments of this aspect include corresponding computer systems, apparatus, and computer programs recorded on one or more computer storage devices, each configured to perform the actions of the methods.

Implementations of the disclosed technology may include one or more of the following features. In some embodiments, the space may include a room in a residential home. In some embodiments, the 3D virtual model representing the 3D geometries of the space is generated based on a set of dimensions corresponding to a floor plan of the room in the residential home, wherein the floor plan is obtained from a builder computing device. In some embodiments, the design element may include an appliance, a bathroom fixture, a cabinet, a door, a hardware element, an electrical fixture, a finish, or a plumbing fixture, or combinations thereof. In some embodiments, the design option for the design element may include a color, a material, a model, or a manufacturer, or combinations thereof. In some embodiments, the image of the design element in the specified design option is generated based on product data catalog data obtained from a builder computing device. In some embodiments, the upgrade price for the design element is configured to replace a price associated with the design element without the specified design option.

Some examples of the method may include obtaining, from the user computing device, a user input specifying an additional design element and a design option for the additional design element located with the space. Further, the method may include updating the 3D virtual model by displaying a modified 3D virtual model, wherein the modified 3D virtual model comprises an image of the additional design element in the specified design option. Finally, the method may update the total price associated with the space based on the generated upgrade price of the additional design element. Implementations of the described techniques may include hardware, a method or process, or a computer tangible medium.

### BRIEF DESCRIPTION OF THE DRAWINGS

The technology disclosed herein, in accordance with one or more various embodiments, is described in detail with reference to the following figures. The drawings are provided for purposes of illustration only and merely depict typical or example embodiments of the disclosed technology. These drawings are provided to facilitate the reader's understanding of the disclosed technology and shall not be considered limiting of the breadth, scope, or applicability thereof. It should be noted that for clarity and ease of illustration these drawings are not necessarily made to scale.

FIG. 1 illustrates an example system for generating automated visualization of a customizable virtual three-dimensional (3D) environment along with objects therein and pricing model, according to an implementation of the disclosure.

FIG. 2 illustrates an example process for generating a 3D visualization of a space, according to an implementation of the disclosure.

FIG. 3 illustrates an example process for placing default design elements within the 3D visualization of the space, according to an implementation of the disclosure.

FIG. 4 illustrates a schematic overview of an example process for machine learning based 3D space visualization, according to an implementation of the disclosure.

FIG. 5A illustrates an example process for creating a prospective buyer user account profile, according to an implementation of the disclosure.

FIG. 5B illustrates an example process for creating a standard buyer user account profile, according, according to an implementation of the disclosure.

FIG. 5C illustrates an example process for creating a homebuyer user account profile, according, according to an implementation of the disclosure.

FIG. 6A illustrates a schematic overview of an example process for design option management, according to an implementation of the disclosure.

FIG. 6B illustrates a schematic overview of an example process for editing design options, according to an implementation of the disclosure.

FIG. 6C illustrates a schematic overview of an example process for adding existing design options, according to an implementation of the disclosure.

FIG. 6D illustrates a schematic overview of an example process for adding new design options, according to an implementation of the disclosure.

FIG. 7A illustrates an example workflow schematic of a prospective buyer user, according to an implementation of the disclosure.

FIG. 7B illustrates an example workflow schematic of a homebuyer user, according to an implementation of the disclosure.

FIG. 7C illustrates an example workflow schematic of a designer user, according to an implementation of the disclosure.

FIGS. 8A-8I illustrate example graphical user interfaces (GUI) for use with a real-time virtual environment customization and pricing system, according to an implementation of the disclosure.

FIGS. 8J-8K illustrate example analytics output within a graphical user interface (GUI) for use by designer user, according to an implementation of the disclosure.

FIG. 9 illustrates an example computing system that may be used in implementing various features of embodiments of the disclosed technology.

Described herein are systems and methods for improving home design process by providing real-time visualization and pricing based on user selections. The details of some example embodiments of the systems and methods of the present disclosure are set forth in the description below. Other features, objects, and advantages of the disclosure will be apparent to one of skill in the art upon examination of the following description, drawings, examples and claims. It is intended that all such additional systems, methods, features, and advantages be included within this description, be within the scope of the present disclosure, and be protected by the accompanying claims.

### DETAILED DESCRIPTION

As alluded to above, selecting design options during a home construction is an inefficient, time-consuming process, often leaving homebuyers frustrated with the choices they made and guessing what the final quote will be. Even if the builder utilizes a visualization software, the program typically does not have detailed product information associated with building customization, including product availability, pricing, or manufacturer details. Instead, these values are typically estimated and reconciled later. Thus, homebuyers are typically left in the dark regarding how each option affects the overall cost of their new home. The present embodiments solve all the foregoing problems by providing an automated computerized 3D interactive design customization, visualization, and pricing system for allowing homebuyers a way to customize construction projects that is real-time, visual, and transparent to both the homebuyer and the builder.

Furthermore, inventory shortages caused by supply-chain, extended lead-times, often forces homebuyers into making “safe” product selections. These products are often selected from a roster of lower-end, often less expensive, and most importantly available products, usually popular with other homebuyers. As a result, homebuyers end up selecting the same product as their neighbors, causing oversaturation, and contributing to the dreaded “cookie-cutter” effect, especially evident within a particular geolocation. Accordingly, because the present system takes into consideration availability of product options, and has an intelligent engine capable of evaluating the selections of other homebuyers made within a real-world location, it provides the homebuyers user with options that are likely to receive high likelihood customer satisfaction, while maximizing builders' profit margin.

Further still, even when builders employ visualization software, the platform frequently depends on dimensions provided by the builder, such as the floor plan or model of the space. However, even if these provided dimensions are accurate, they overlook any modifications or customizations. Consequently, homebuyers are presented with visualizations of spaces that do not accurately reflect the actual layout.

In some embodiments, present embodiments provide an automated computerized 3D visualization of the space by enhancing the floor plan dimension data that uses a 3D engine which combines blueprint renderings and images, with data collected using remote sensing technologies, e.g., Light Detection and Ranging (LiDAR), Structured Light Depth Sensing, and/or in conjunction with other technologies employed by optical cameras of smartphones (e.g., computational photography and depth-sensing algorithms, advanced processing algorithms), and other such similar technologies.

Moreover, typical builder models feature a standard set of design options, ranging from appliances to cabinet styles to paint colors. Conventional visualization software often generates only an approximation of these design elements, leaving customers with an incomplete understanding of the final home. By employing machine learning to enhance the visual renderings of default design selections within a space, the present innovations deliver a more precise representation to buyers without overburdening the computational resources typically associated with 3D models.

It is to be understood that both the foregoing general description and the following detailed description present example and explanatory embodiments of the invention, and are intended to provide an overview or framework for understanding the nature and character of the invention as it is claimed. The accompanying drawings, photographs, and attachments are included to provide a further understanding of the invention and are incorporated into and constitute a part of this specification. The drawings illustrate various example embodiments of the invention, and together with the description, serve to explain the principles and operations of the invention.

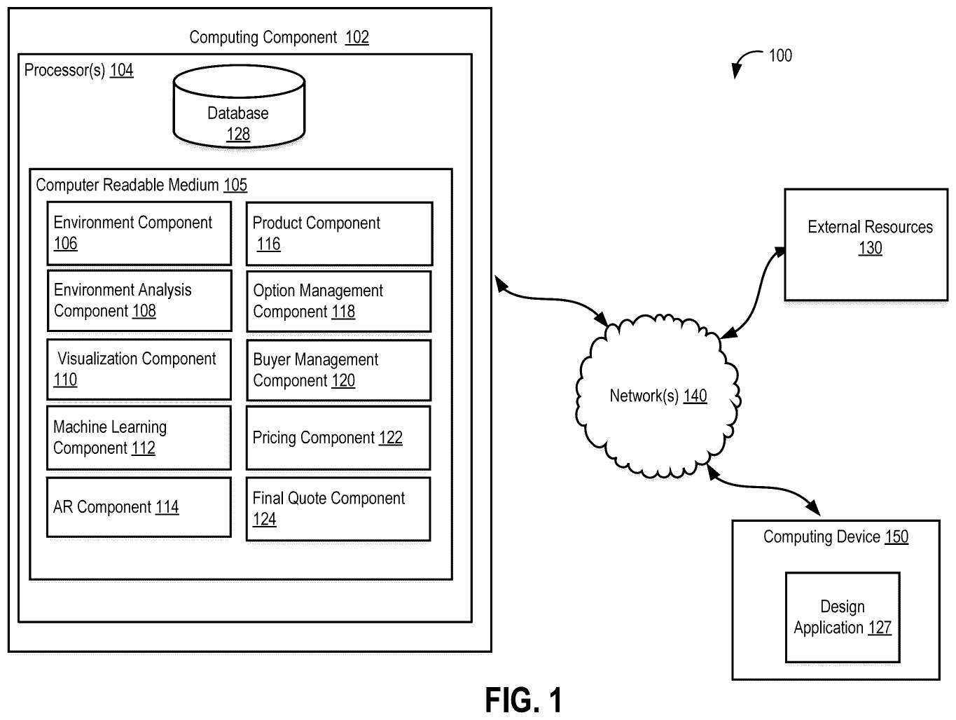

FIG. 1 illustrates a diagram of a system 100 for generating an automated visualization of a customizable virtual 3D environment along with objects therein and pricing model, in accordance with the embodiments disclosed herein.

This example system 100 may include a computing component 102 in communication with a network 140. The system 100 may also include one or more external resources 130 (e.g., an online repository of existing floor plans, home models, and/or product details maintained by a builder), a datastore 128, and a client computing device 150 that is in communication with network 140. External resources 130 may be located in a different physical or geographical location from the computing component 102.

As illustrated in FIG. 1, computing component or device 102 may be, for example, a server computer, a controller, or any other similar computing component capable of processing data. In the example implementation of FIG. 1, computing component 102 includes a hardware processor 104 configured to execute one or more instructions residing in a machine-readable storage medium 105 comprising one or more computer program components.

In some embodiments, client computing device 150 may include a variety of electronic computing devices, for example, a computer wearable device, such as smart glasses, or any other head mounted display devices that can be used by a user (e.g., a homebuyer). In some embodiments, the computer wearable device may include a transparent heads-up display (HUD) or an optical head-mounted display (OHMD). In other embodiments, client computing device 150 may include other types of electronic computing devices, such as, for example, a smartphone, tablet, laptop, virtual reality device, augmented reality device, display, mobile phone, or a combination of any two or more of these data processing devices, and/or other devices.

In some embodiments, client computing device 150 may include one or more components coupled together by a bus or other communication link, although other numbers and/or types of network devices could be used. For example, client computing device 150 may include a processor, a memory, a display (e.g., OHMD), an input device (e.g., a voice/gesture activated control input device), an output device (e.g., a speaker), an image capture device (i.e., optical sensors (such as CMOS or CCD sensors) which convert incoming light into electrical signals, which are then processed by the client computing device 150 image signal processor (ISP) to generate digital images and or digital videos, a LiDAR sensor configured to obtain light detection and ranging data, a structured light depth sensor configured to capture 3D information about objects or environments using structured light patterns, and or other such sensors that may be employed by client computing device 150 which may be used in conjunction with other technologies (e.g., computational photography and depth-sensing algorithms, advanced processing algorithms), and a communication interface.

Hardware processor 104 may be one or more central processing units (CPUs), semiconductor-based microprocessors, and/or other hardware devices suitable for retrieval and execution of instructions stored in computer readable storage medium 105. Processor 104 may fetch, decode, and execute instructions 106-122, to control processes or operations for generating real-time visualizations and pricings of virtual environment based on buyer's selections. As an alternative or in addition to retrieving and executing instructions, hardware processor 104 may include one or more electronic circuits that include electronic components for performing the functionality of one or more instructions, such as a field programmable gate array (FPGA), application specific integrated circuit (ASIC), or other electronic circuits.

A computer readable storage medium, such as machine-readable storage medium 105 may be any electronic, magnetic, optical, or other physical storage device that contains or stores executable instructions. Thus, computer readable storage medium 105 may be, for example, Random Access Memory (RAM), non-volatile RAM (NVRAM), an Electrically Erasable Programmable Read-Only Memory (EEPROM), a storage device, an optical disc, and the like. In some embodiments, machine-readable storage medium 105 may be a non-transitory storage medium, where the term “non-transitory” does not encompass transitory propagating signals. As described in detail below, machine-readable storage medium 105 may be encoded with executable instructions, for example, instructions 106-122.

As noted above, hardware processor 104 may control processes/operations for generating an automated visualization of a customizable virtual 3D environment along with objects therein and a pricing model by executing instructions 106-122.

Hardware processor 104 may execute instruction 106 configured to obtain environment information (e.g., design name, floor plan, floor plan options, and so on) provided by the builder and upload it to database 128. In some embodiments, environment information may include a set of design elements that are associated with a particular home floor plan or model by default. These design elements may include, for example, cabinetry of a particular configuration and color, fixtures, finishes and so on.

Alternatively, instruction 106 may be configured to obtain LiDAR data from client computing device 150 operated by a user (e.g., a homeowner). The client computing device 150 may be a smartphone equipped with a LiDAR sensor or any other such device capable of gathering LiDAR data. LiDAR is a technology that measures distance to a target by illuminating the target (e.g., using laser light) and then measuring the reflected light with a sensor (e.g., measuring the time of flight from the laser signal source to its return to the sensor). Digital 3D representations of the target can then be made using differences in laser return times and wavelengths. LiDAR may be used to measure distances (e.g., the distance from a LiDAR camera to an object, the distance between objects, and so forth). By virtue of using LiDAR results in more accurate measurements of dimensions of a space as compared with other methods (i.e., manual measuring). Furthermore, smartphone camera may be used to obtain environment information. For example, the smartphone camera data gathered by client computing device 150 may include color data, pixel data, and so on. Together, the gathered LIDAR sensor and camera data may be analyzed to determine the dimensions of a particular space (e.g., a house) or a part of the space (e.g., a room inside the house), including the dimensions of one or more objects in the room (a window or a door).

Hardware processor 104 may execute instruction 108 configured to analyze environment information obtained by component 106, including dimension data of the space and dimension data of one or more default design elements associated with the space. Hardware processor 104 may execute instruction 110 to generate a 3D visualization of the space including various design elements within the environment and/or design elements selected by the user. Hardware processor 104 may execute instruction 112 configured to execute various software applications and components of the system for machine learning based recommendations for default design element dimensions and placement in a 3D visualization.

Hardware processor 104 may execute instruction 116 configured to obtain product and price information provided by the builder and upload it to database 128. Hardware processor 104 may execute instruction 118 to initiate to initiate a “designer” interface configured to provide designer users (i.e., users associated with the builder user) with an ability to manage “homebuyer” users and options generated by the product data upload component 116. Hardware processor 104 may execute instruction 120 to initiate a “homebuyer” interface configured to receive product option selections made by the buyer user. Hardware processor 104 may execute instruction 122 to update the visualization of a design element category within an environment based on the option selections received by 116. Hardware processor 104 may execute instruction 124 to generate a final quote for the entire project.

In utilizing system 100, a builder user or a homebuyer user may access and operate a web application, a software application, a mobile application, or the like on the client computing device 150, such as, but not limited to computers, smartphones, tablets, virtual reality devices, augmented reality devices, computer-wearable devices, such as smart glasses, or any other head mounted display devices including HUD and/or OHMD, as alluded to earlier, and the like. Users may utilize client computing device 150 to display each of the builder and homebuyer interfaces discussed herein. For example, designers and homebuyers may use design application 127 running on the client computing device 150 and communicating with computing component 102 via network 140.

The computing component 102 may be programmed to perform processing functions of the system and provide instructions to the client computing device 150 for display each of the builder and buyer interfaces discussed herein. For example, designers and homebuyers may use design application 127 running on the client computing device 150 and communicating with computing component 102 via network 140.

### Obtain Environment Information

As alluded to above, instruction 106 may be configured to obtain environment information (e.g., a design name, a floor plan, a floor plan option, room and space dimensions, measurements, and so on) provided by the builder and upload it to database 128. In some embodiments, the builder may provide a 2D model of the space. For example, this can be a blueprint or a drawing of a floorplan for a space provided by the builder. In some embodiments, environment information may be obtained from an online repository of existing floor plans or home models maintained by the builder (e.g., an external resource 130). In some embodiments, the builder may indicate which floor plan(s) correspond to which home model, thereby facilitating obtaining environment information. In this case, environment information may be associated with a particular floor plan.

In some embodiments, environment information may include dimension data (e.g., associated with a particular floor plan or home model). For example, the data may include a length, a width, and a height of a room(s) along with objects with the room (e.g., windows, doors, and so on). The raw dimension data may be extracted from the obtained floor plan and uploaded to a dimensions database (e.g., database 128) in accordance with a data schematic. The data schematic may be previously determined (e.g., by a system administrator) or automatically determined (e.g., by applying machine learning algorithms).

In some embodiments, some or all of dimension data may be obtained using a smartphone (e.g., client computing device 150) operated by the user. For example, a homeowner looking to renovate a room in their house may obtain room measurements captured by user smartphone. These measurements may include one or more optical images, radar scans, LiDAR scans and/or sonar scans of the space, for example. In other words, rather than manually measuring the room and entering dimensions, the homeowner may employ their smartphone to gather dimension data. Data obtained by the user may be loaded to database 128.

System 100 may use dimension data uploaded to database 128 (e.g., dimension database) to generate a 3D virtual model representing three-dimensional geometries of individual spaces within a home. As discussed, the dimension data used to generate a 3D model of the space may be obtained from a plurality of sources, including a 2D model (e.g., a blueprint of a floor plan or a home model) provided by the builder or a dimension data file. Dimension data may be extracted from the blueprint file, and in some cases supplemented with data captured by user's client computing device 150, including optical images, radar scans, LiDAR scans and/or sonar scans when analyzed to generate a 3D virtual model. In those instances where builder data is not available, LiDAR or such similar data may be the only source of dimension data. For example, LiDAR data may be used create a 3D point cloud model (e.g., a set of data points in space) of a room by measuring many points in the room or landscape. A point cloud consists of huge amounts of data points in three dimensions (with X, Y and Z coordinates). The point cloud gathering can be done with a laser or sonar scanner, for example. Furthermore, as is understood in the art, 3D point clouds may be converted to 3D surfaces (e.g., by using techniques such as Delaunay triangulation, alpha shapes, or ball pivoting to build a network of triangles over existing vertices of the point cloud).

In some embodiments, dimension data extracted from the floor plan may be used as a starting point when generating a 3D virtual model of the space and any objects therein. Subsequently, the 3D model may be further refined or enhanced with digital images of various home design element options (such as flooring, cabinets, and so on) by passing them to a 3D rendering engine to coalesce the images.

In some embodiments, pricing information associated with individual design elements may be attached to each option and a pricing engine may be used to calculate the total pricing displayed in real time.

In some embodiments, the same dimension data used to construct the 3D virtual model of the space may also be applied to generate dimensions of default design elements associated with a particular home floor plan or home model. For example, a particular floor plan may come with a shaker style white kitchen cabinetry, as indicated by the builder. In this case, system 100 may determine cabinets dimensions based on the dimension data of the kitchen. By virtue of determining individual dimensions of each design element within the scale of the overall space allows the system to generate a more realistic virtual 3D rendering. In some embodiments, information related to individual design elements (i.e., style details, color, texture, dimensions, and so on) may be obtained from product detail files provided by the builder. For example, the builder may provide one or more files including a catalog of customization options, i.e., a product catalog. The product catalog may include a plurality of data points related to each design element option (e.g., design object or design element, such as light fixture, cabinet, faucet, and so on), including object type, object size, object dimensions, model information, color, color options, one or more images, price, and availability. Additionally, the product detail file may specify options associated with a particular home and/or floorplan model.

In some embodiments, dimension data determined by system 100, as explained above, may be used to construct a customizable 3D visualization of a space including objects within the space. For example, dimension data determined from the floor plan obtained from the builder may be used. In other embodiments, optical images, radar scans, LiDAR scans and/or sonar scans of the space, may be used alone (e.g., when dimension data cannot be obtained from the builder) or to supplement the dimension data provided by the builder. For example, LiDAR data may be used to create a partial or complete 3D model of the space, and may include 3D point cloud(s) created from the LiDAR data. In some embodiments, the virtual 3D model may be generated from images of the room using 3D reconstruction methods, such as: multi-view stereo, structure-from-motion, monocular cues methods, such as shape-from-shading, photometric stereo, shape-from-texture, and/or any other suitable techniques. In some embodiments, the virtual 3D model can also be automatically generated from architectural diagrams (e.g., from those provided by the builder).

As alluded to above, dimension data obtained and analyzed may be used to determine individual default design element measurements including size, scale, and placement within the space. For example, a set of default design elements may be provided by the floor plan or home model. Upon identifying the design elements, system 100 may generate individual images of each element using dimension data provided by builders (e.g., product detail catalogs). For example, data obtained from the product catalog may be used to generate images of design elements used to populate individual spaces within the 3D virtualization of the space. As the buyer selects new options, the visualization of those options may include updating previously generated images. In other embodiments, dimension data of an element may be received from user client computing device 150 equipped with an optical sensor, a radar sensor, a LiDAR sensor, a sonar sensor, and other such similar remote sensing sensors. Color data associated with design element may be determined using color description or may be captured by an image capture device equipped with an optical sensor.

In some embodiments, the design objects rendered within the 3D virtual representation of the space may be generated using one or more processes. For example, the dimension data may be read by a gaming engine (e.g., the UNREAL engine or UNITY engine) to generate a design object rendering for display in the 3D virtual representation of the space within the homebuyer's GUI. For example, am image of a particular design element (e.g., a kitchen faucet) may be provided to a gaming engine which will render a set of realistic views and coalesce the views to generate a 3D image of the design element. The 3D image of the design element will be rendered based on the object type, object dimensions, space dimensions, and so on. Various factors may be taken into consideration (e.g., including placement, movement, view angle, other objects in the vicinity that may cause shading, and so on).

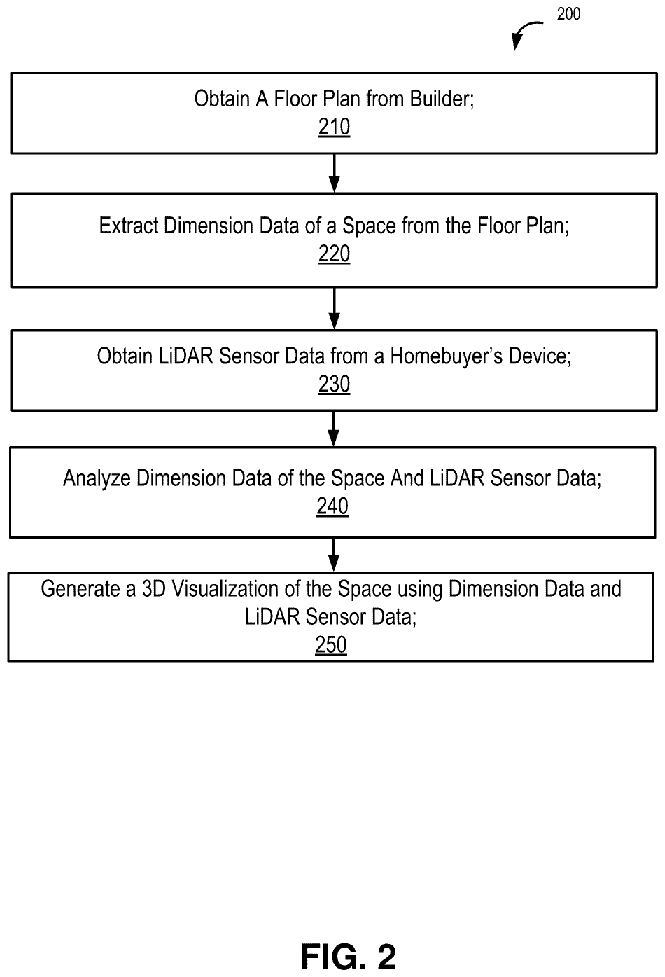

FIG. 2 shows a flowchart of an exemplary computer-implemented method 200 of generating a 3D visualization of a room within a home. With reference thereto, at step 210, component 108 illustrated in FIG. 1 receives environment data. For example, floor plan identifying buyer's home is received from a builder server (e.g., external resource 130 illustrated in FIG. 1). At step 220, dimensions of the room provided by the floor plan are extracted and saved to database 128. At step 230, optical image data, radar scan, LiDAR scan data and/or sonar (e.g., from a user computing device 150 illustrated in FIG. 1 equipped with remote sensing sensor such as a LiDAR sensor and a camera) is received, such as via wireless communication or data transmission over one or more radio frequency links, by component 108 of computing component 102. In some embodiments, the remote sensing data such as LiDAR data may be transferred to the computing component 102 from the LiDAR sensor equipped camera 150 via a physical memory device. At step 240, the component 108 illustrated in FIG. 1 determines a plurality of dimensions of a room of a home based upon processor analysis of the dimension data extracted from the floor plan and remote sensing data, such as LiDAR data, captured by the user computing device 150. In this respect, LiDAR data provides more accurate measurements than floor plan data alone. The dimensions measured may include dimensions of the space including permanent fixtures such as doors and windows.

At step 250, component 110 may generate a 3D visualization of the room based on the derived dimensions. The 3D visualization may further be based upon data from a user computing device 150 illustrated in FIG. 1 equipped with a camera and/or a LiDAR sensor and builder data from external resource 130 and saved to database 128. For instance, the model may include dimension data of an object from the LiDAR data, and color data of the object from the camera data. In some embodiments, the user may navigate through the 3D visualization of the room using arrows (e.g., the user supplies navigational data to the computing component 102 by clicking on the arrows of the 3D visualization).

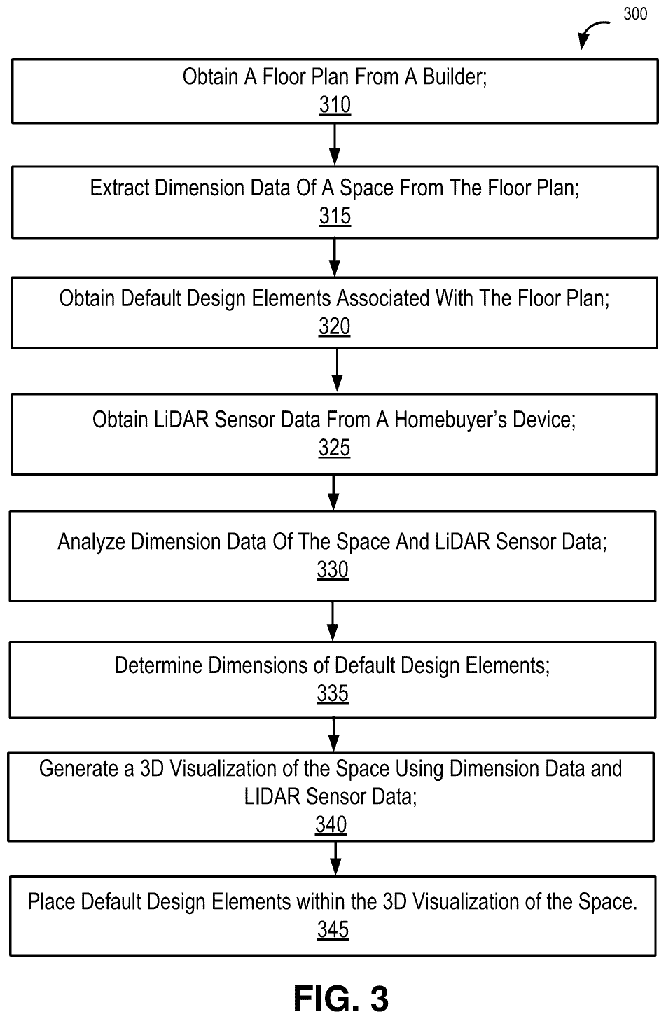

FIG. 3 shows a flowchart of an exemplary computer-implemented method 300 of generating a 3D visualization of a room within a home including the placement of default design elements. Similar to the process illustrated in FIG. 2 and described above, at step 310, component 108 (illustrated in FIG. 1) receives environment data, e.g., a floor plan identifying buyer's home received from a builder server. At step 315, dimensions of the room provided by the floor plan are extracted and saved to database 128 (illustrated in FIG. 1). Next, at step 320, data associated with default design elements is obtained from a builder server (e.g., external resource 130 illustrated in FIG. 1). At step 325, LiDAR data (e.g., from user computing device 150 equipped with a LiDAR sensor and camera illustrated in FIG. 1) is received, such as via wireless communication or data transmission over one or more radio frequency links, by component 108 of computing component 102 (illustrated in FIG. 1). In some embodiments, the LiDAR data is transferred to the computing component 102 from the LiDAR sensor equipped camera 150 via a physical memory device. At step 330, component 110 (illustrated in FIG. 1) determines a plurality of dimensions of a room of the home based upon processor analysis of the dimension data extracted from the floor plan and LiDAR data. At step 335, component 110 determines dimensions of default design elements associated with floor plan obtained from the builder. At step 340, component 110 (illustrated in FIG. 1) may generate a 3D visualization of the room based on the derived dimensions. At step 345, default design elements are placed within the 3D visualization of the room based on the derived dimensions in step 335.

As alluded in reference to FIG. 1, a machine learning algorithm may be used to analyze any or all the data held by computing component 102. The machine learning algorithm may be a supervised learning algorithm, employ decision trees, make use of an artificial neural network, make use of Bayesian statistical analysis, or combinations thereof. In this regard, a processor or a processing element may be trained using supervised or unsupervised machine learning, and the machine learning algorithm may employ a neural network, which may be a convolutional neural network, a deep learning neural network, or a combined learning module or program that learns in two or more fields or areas of interest. Machine learning may involve identifying and recognizing patterns in existing data in order to facilitate making predictions for subsequent data. Models may be created based upon example inputs in order to make valid and reliable predictions for novel inputs. It should be understood that, over time, the computing component 102 may accumulate a large pool of data on an individual home or a group of homes. The data described above may be used (e.g., with a machine learning algorithm described above or by any other technique) to generate a 3D visualization of the room. The machine learning algorithm may be trained using previously known data.

In some embodiments, the machine learning algorithm component 112 comprises a machine learning algorithm for recommending default design element dimensions and placement in a home. Exemplary types of default design elements that the machine learning algorithm may provide a recommendation for default design element dimensions and placement are cabinets, floors, windows, etc. However, the machine learning algorithm 112 may provide a recommendation for dimensions and placement of any kind of object.

The machine learning algorithm 112 may be trained using historic data (e.g., from database 218, or external resources 130, etc.). The historic data may include data of design element dimensions and placement within a room of a home. In some embodiments, this historic data may be generated from analysis of builder's websites and previously generated 3D home visualization as well as reality websites (e.g., online websites used to advertise houses for sale).

The machine learning algorithm 112 may be used to analyze any or all the data held by computing component 102 and/or database 218. The machine learning algorithm 112 may be a supervised learning algorithm, employ decision trees, make use of an artificial neural network, make use of Bayesian statistical analysis, or combinations thereof. In this regard, a processor or a processing element may be trained using supervised or unsupervised machine learning, and the machine learning algorithm may employ a neural network, which may be a convolutional neural network, a deep learning neural network, or a combined learning module or program that learns in two or more fields or areas of interest. Machine learning may involve identifying and recognizing patterns in existing data in order to facilitate making predictions for subsequent data. Models may be created based upon example inputs in order to make valid and reliable predictions for novel inputs. In some embodiments, the machine learning algorithm is a convolutional neural network (CNN); in some embodiments, the machine learning algorithm is a deep neural network (DNN); in some embodiments, the machine learning algorithm is a recurrent neural network (RNN). It is advantageous to use machine learning algorithms that are particularly adept at finding patterns (e.g., CNNs).

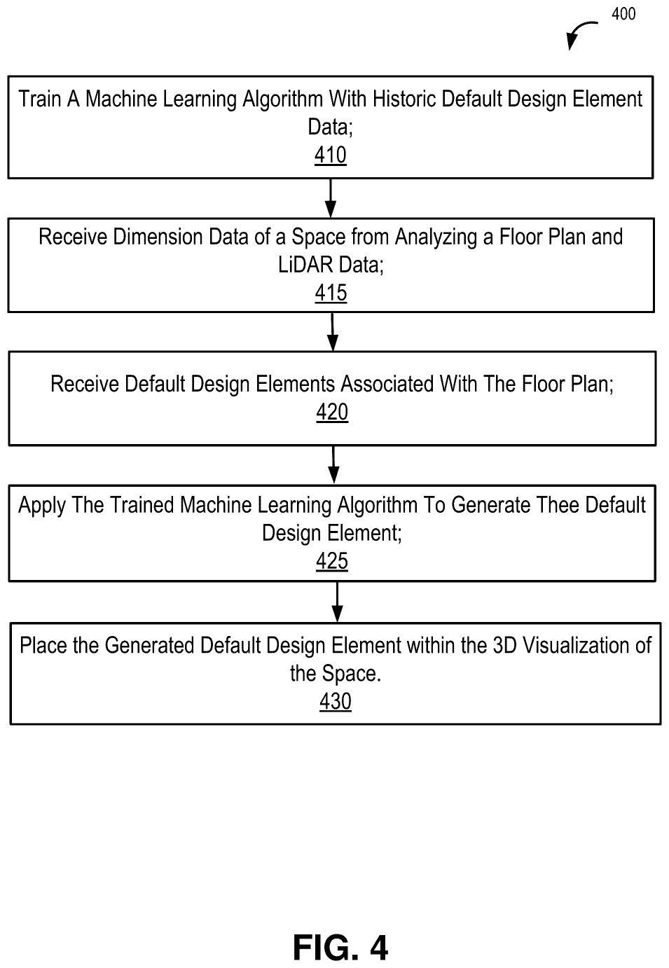

FIG. 4 shows a flowchart of an exemplary computer-implemented method 400 for machine learning based recommendations for default design element dimensions and placement within a space. With reference thereto, at step 410, a machine learning algorithm, such as a CNN, DNN, or RNN, is trained. The machine learning algorithm may be trained using any data, such as data of default design elements in a room. This data may be gathered from, for example, database 128 and/or database within external resources 130 (as illustrated in FIG. 1).

At step 415, the system receives environment data. The environment data may comprise dimension data of the room (e.g., length, width, and/or height of the room), color data of the room, and other data of the room (e.g., window, door, and/or skylight placement in the room). At step 420, design element data is received. The design element data may comprise dimension data of the design element, type of the design element, and/or color data of the design element, and so on. The design element data may be received from a number of source(s) including a builder catalog, an external database or website. At step 425, using the trained machine learning algorithm, the system generates a default design element dimensions and placement recommendation based upon the received environment data and the received design element data. At step 430, the generated design element is placed within the 3D visualization of the room based upon the recommendation for placement of the element for viewing by the buyer user on a buyer client computing device.

Referring back to FIG. 1, in some embodiments, hardware processor 104 may execute instruction 114 configured to provide augmented reality (AR) functionality for enhancing homebuyer experiences. The system 100 may implement AR for any of a variety of different applications, examples of which are described elsewhere herein. For example, system 100 may include an exemplary AR engine (not illustrated). The exemplary AR engine may be an of a computer-implemented system that generates AR content for use by the system 100. Alternatively, the AR engine could also or instead be provided by another component residing within or external to the system 100. In some embodiments, application 127 may provide an AR engine that is available to homebuyer users and/or designer users. The system 100 may include multiple AR engines that are provided by one or more parties. The multiple AR engines may be implemented in the same way, in similar ways and/or in distinct ways. In addition, a portion of an AR engine may be implemented in the user computing device 150. For example, the user computing device 150 may store and run an AR engine locally as a software application.

The AR engine may implement some of the functionality described herein. Although the embodiments described below may be implemented in association with the components of the system 100, the embodiments described below are not limited to the specific system 100 of FIG. 1. Further, the embodiments described herein do not necessarily need to be implemented in association with or involve the components of the system 100 at all. In general, any applications of AR could implement the systems and methods disclosed herein.

AR can supplement a user's real-world environment with virtual content to alter the user's perception of the real-world environment. Through a process known as simultaneous localization and mapping (SLAM), a representation of a user's real-world environment and a position of the user within that real-world environment can be continuously or intermittently determined by an AR engine. It should be noted that, as used herein, a position can include both an orientation and a location. An AR experience for the user can then be generated by mapping one or more virtual models to the representation of the real-world environment. AR content for the user may include renders of the virtual models that are overlaid onto the real-world environment. The renders are generated to reflect the relative position of the user in the real-world environment and the mapping of the virtual models to the real-world environment. In this way, the AR content may provide near-seamless integration of the virtual models with the real-world space for the user.

AR can allow a homebuyer to view and interact with a virtual design element when the buyer is not able to interact with a physical product. For example, AR can superimpose a virtual representation of cabinetry or flooring onto a real-world environment that is captured in an image, which can make the product appear to be present in the real-world environment. The image could be of a model home or homebuyers unfinished home or another location that is relevant to the homebuyer, allowing the homebuyer to view the product in an environment that is of interest to them. In some implementations, builders may use AR to enable customers to view virtual fixtures and/or design element options within model homes or a home that is being built. For example, a virtual representation of tile can be superimposed on a video stream of a bathroom of a model home using AR, allowing the size and look of the tile in the bathroom to be appreciated. In some embodiments, AR content may be rendered onto a real-world environment that is captured in an image or video stream of a computer wearable device, such as smart glasses, or any other head mounted display devices that can be used by the homebuyer.

Referring back to FIG. 1, in some embodiments, system 100 may be utilized by individual builders (e.g., as a white label product). In this implementation, each instance of the system may be accessed and used by a separate builder entity. Designer users (i.e., employees of the builder) will assist and guide homebuyer users they have been assigned to. They will be given access to the profile of those respective buyers.

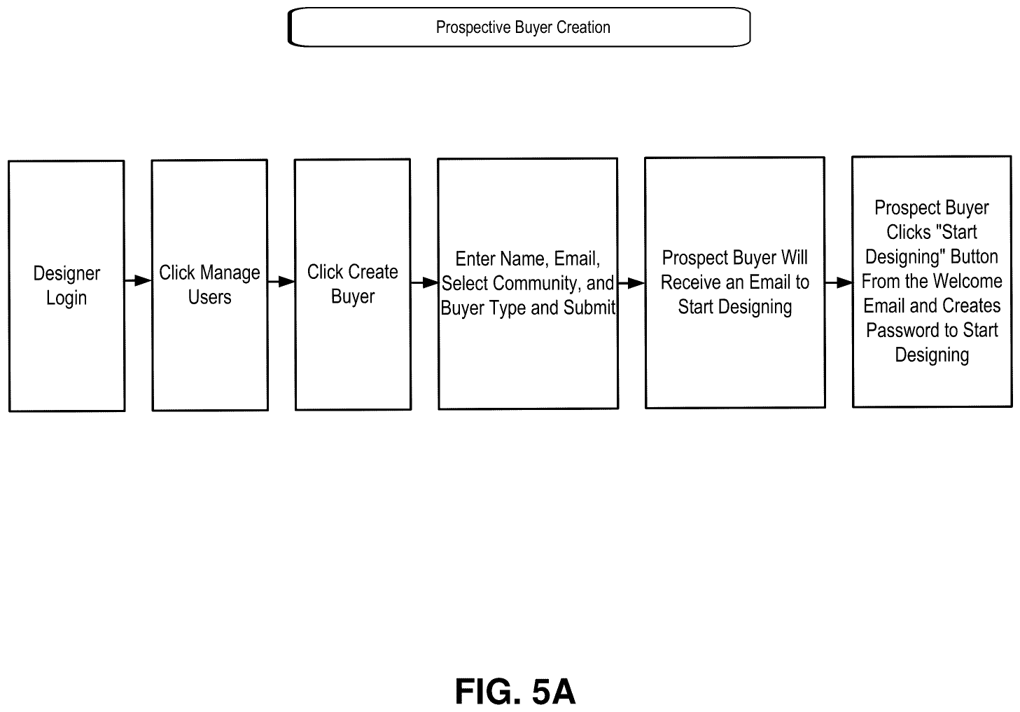

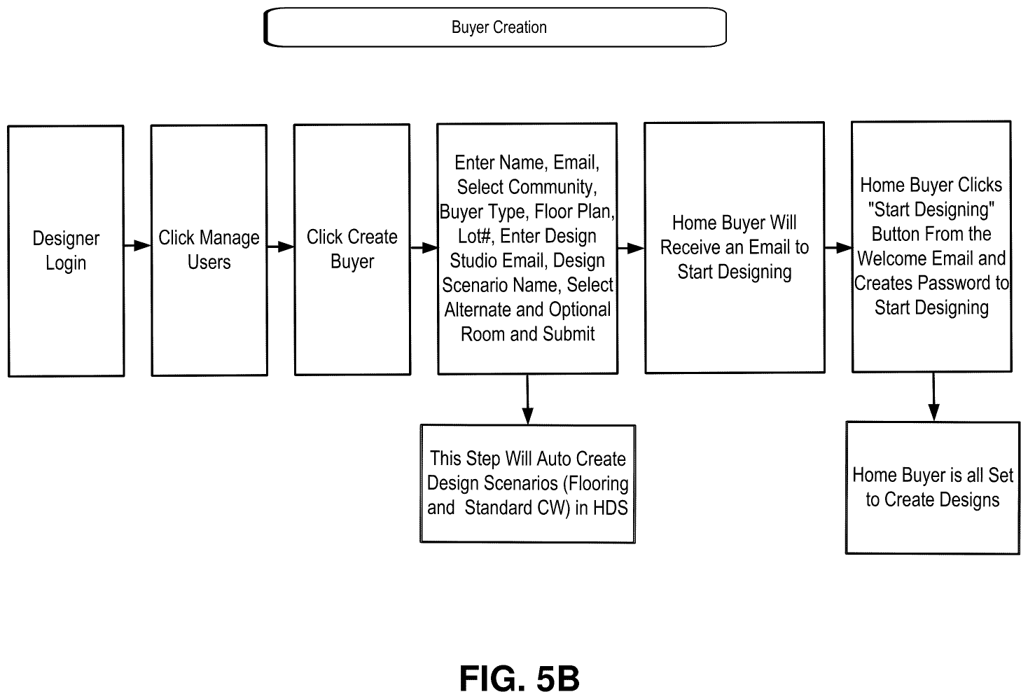

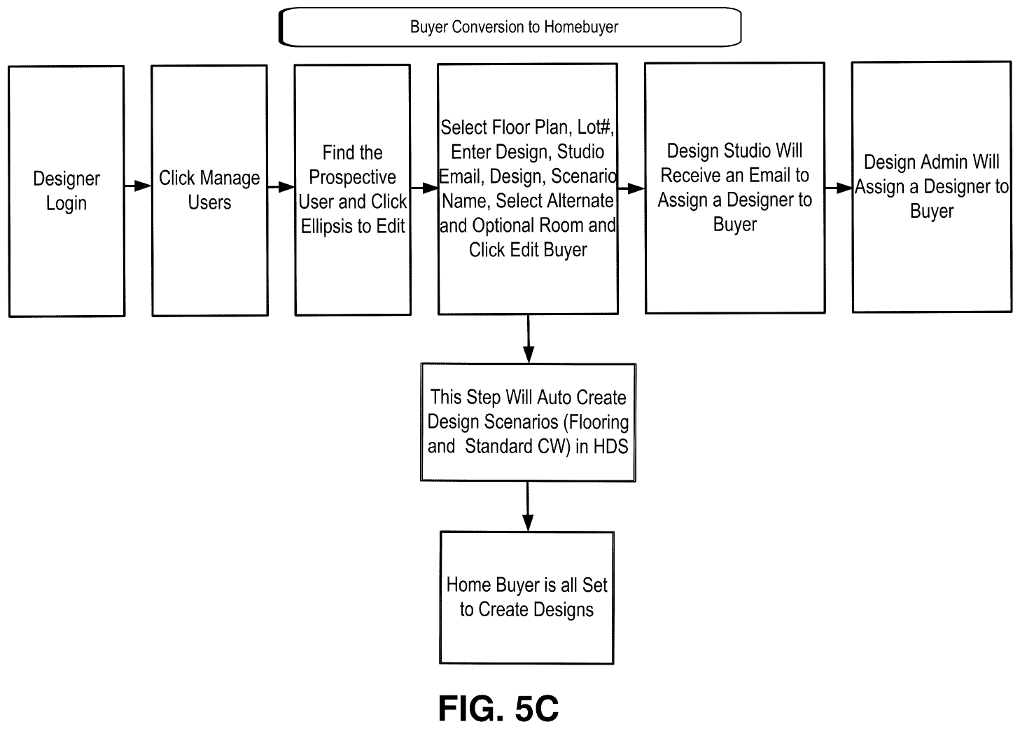

Some designer users, design admins, will be given a special access to functions of the system 100 available only to such designer admin users. Designer admin users who will behave like a designer user but will also get access to additional application features related to management of buyers. For example, designer admin users may create and manage profiles associated with buyer users. As illustrated in a schematic in FIG. 5A, a designer admin user may create a profile associated with a prospective buyer. The prospective buyer user will be notified via email that they can begin their design project. Prospective buyers will access a simplified version of the design application 127 generated by computing component 102. Similarly, designer admin user may create a profile associated with a standard buyer (i.e., not prospective), as illustrated in FIG. 5B. In response, the buyer user will receive an email notification prompting them to access design application 127 on their computing device 150. Unlike the prospective buyer, standard buyers will have access to a plurality of automatically generated design scenarios. The designer admin user can also manage users by accessing respective user profiles. For example, as illustrated in in a schematic in FIG. 5C, a designer user may convert a prospective buyer to a homebuyer. Further, designer admin user can assign designer users for assisting homebuyer users, as explained above. The homebuyer user will be notified via email that a designer has been assigned to help with their project.

As alluded to above in reference to FIG. 1, instruction 116 may be configured to obtain product data, product availability, and product price information provided by the builder user via client computing devices 150 and storage on the computing component 102 or in a different location. For example, a builder user may upload one or more files comprising a catalog of customization options, i.e., a product catalog. The product catalog may include a plurality of data points related to each design element option along with its price and availability and/or delivery information. Additionally, the product data file may specify which options are associated with which home and/or floorplan models. Finally, the product data file may include dependencies used to determine menu options for user selection, as explained further below. In some embodiments, the information may include manufacturer details, including shipping lead time and similar data. For example, the product data catalog may be provided by the builder as one or more .csv files. The instruction 116 may be configured to parse the data in the builder product data catalog file and upload to an options database (e.g., database 128) based on a data schematic. In other embodiments, the builder may utilize a GUI provided by application 127 to populate the options database directly. Further still, the builder may provide a file in a format previously not utilized by system 100. The instruction 116 may be configured to utilize machine learning to use historic product data catalog to automatically determine appropriate data categorization.

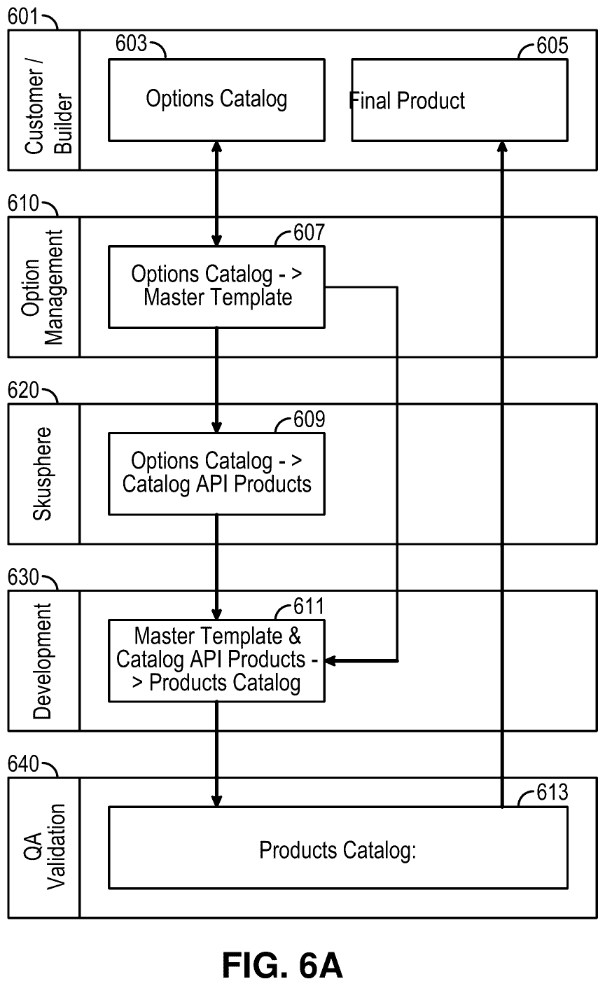

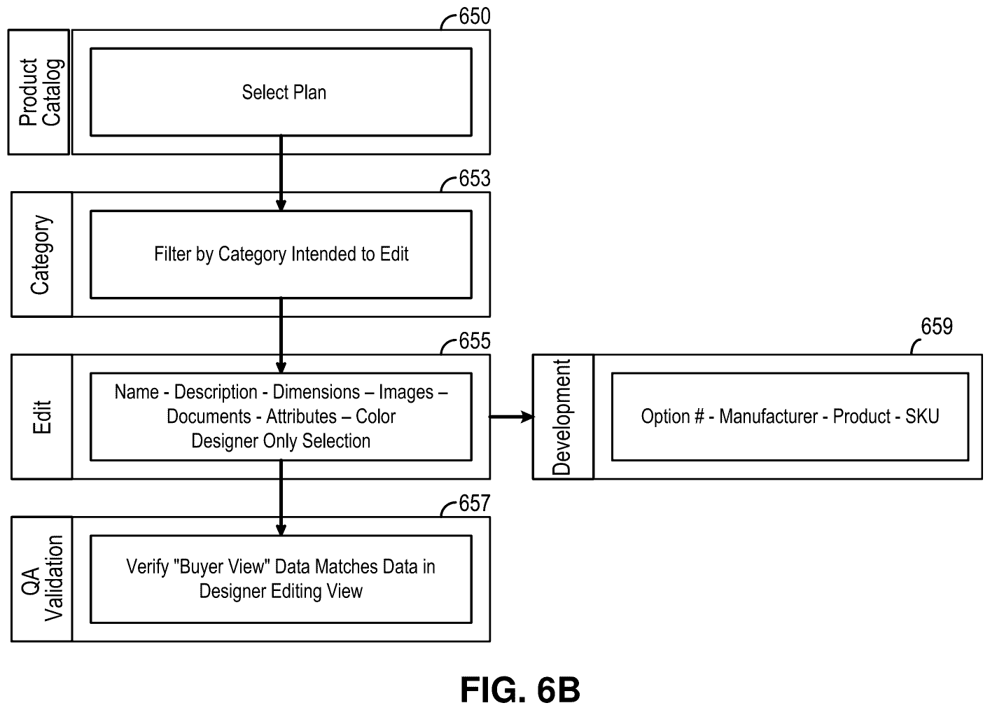

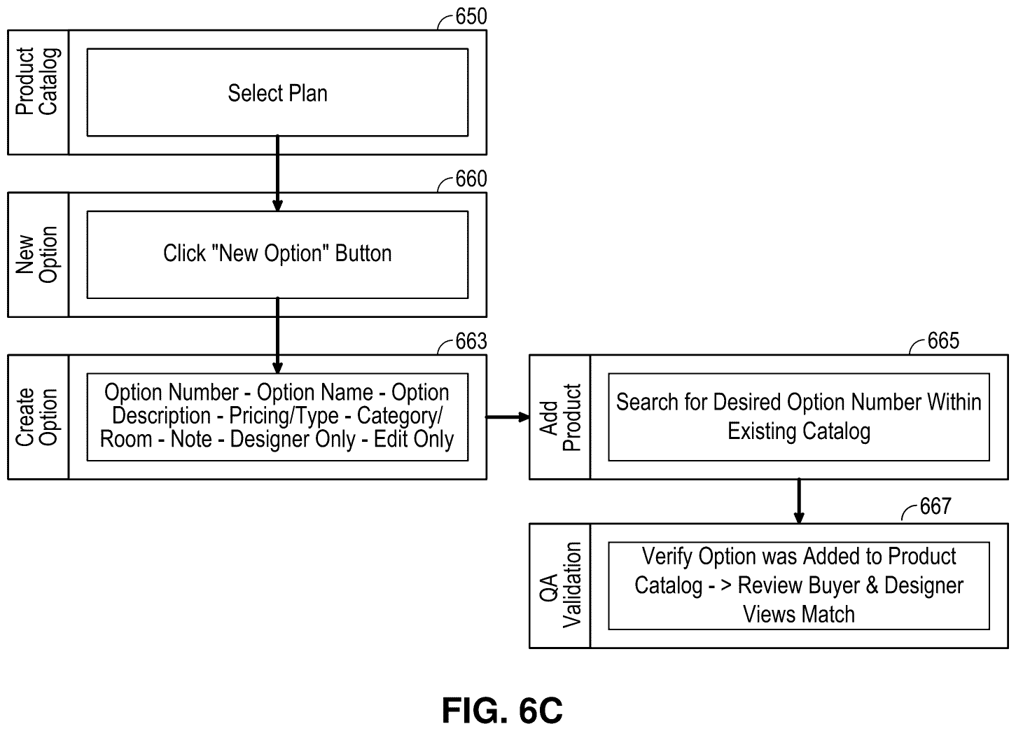

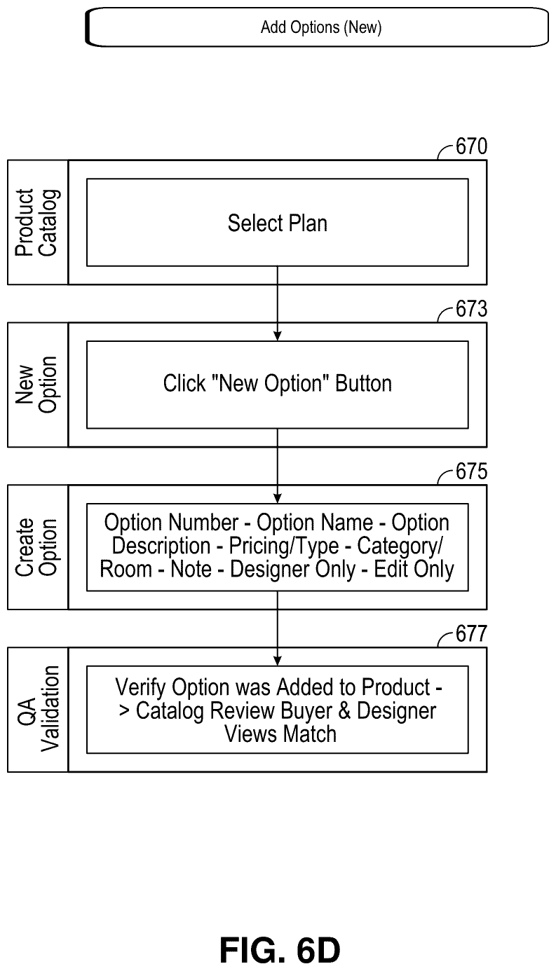

Hardware processor 104 may execute instruction 118 to initiate a “designer” interface configured to provide designer users with an ability to manage options generated by the product data upload component 116. For example, a schematic illustrated in FIG. 6A, shows exemplary processes associated with providing design option management. The workflow includes a customer/builder process 601, an option management process 610, a SKUsphere process 620, a development process 630, and a QA validation process 340.

The customer/builder process 601 includes access to an options catalog 303 which stores data obtained from the product data file provided by the builder. Next, within the option management process 610, the options catalog is used to generate a master template 307. The master template includes all the options associated with a particular home design model.

The SKUsphere process 620 is configured to translate the identification numbers used by the builder into supplier purchase order Stock-Keeping Unit (SKU) with the help of catalog API 609. The catalog API 609 provides the integration layer between options catalog 603 and the master template 607 to determine supplier SKUs. Generally speaking, in computer programming, an API is a set of routines, protocols, and tools for building software applications. An API provides the building blocks for a computer program, which are put together by a programmer. An API defines functionalities in terms of its operations, inputs, outputs, and underlying types that are independent of their respective implementations, which allows definitions and implementations to vary without compromising each other. In addition to accessing databases or computer hardware, such as hard disk drives or video cards, an API can ease the work of programming GUI components. APIs often come in the form of a library that includes specifications for routines, data structures, object classes, and variables. The result of the SKUshere process 620 is the products catalog 611 which includes options with correct supplier information. The products catalog 611 is used by the development process 630 to generate views for the buyer and the designer users. The QA validation process 640 performs data validation and updates final product catalog 605 with new product data.

Designer users may be able to view and edit the options generated by the system in response to the uploading the product data files. For example, a schematic illustrated in FIG. 6B, shows exemplary processes associated with editing design options. The editing process includes selecting a plan 650, filtering the options by category 653, performing a modification to an option 655 including changing design element name, description, dimension, images, documents, attributes, color, and so on. Next, the edit process includes a QA validation process 657 configured to provide use with a way to validate the modification. Once the QA validation process 657 is completed, the edited design option is published to the product catalog.

Designer users may be able to add options to an existing catalog, as illustrated in a schematic in FIG. 6C, showing exemplary processes associated with adding design options. The process includes selecting a plan 650, clicking on the “New Option” button 660, creating a new option by inputting design element name, description, pricing information, and category 663, searching for desired number with existing catalog 665, and validating that the option was added in a QA validation process 667. Finally, design users may be able to add options to a new catalog, as illustrated in a schematic in FIG. 6D, showing exemplary processes associated with adding design options to a new catalog. The process includes selecting a plan 650, clicking on the “New Option” button 673, creating a new option by inputting design element name, description, pricing information, and category 675, and validating that the option was added in a QA validation process 677.

Referring back to FIG. 1, instruction 120 may initiate a “homebuyer” interface configured to receive design option selections made by the buyer user. The buyer interface may be accessible from a user computing device 150, wherein the design application 127 provides a means for the buyer to make a plurality of selections of options based on accessing a plurality of catalogs, and menus associated with each room and model design, and in accordance with model, floorplan, dependency rules and other parameters. The options may be sorted in accordance with buyer's prior history, design preferences, delivery lead time, price, and other buyer-specific parameters. Upon selecting a design option that causes a significant increase to the total quote or time due to lead time or supply chain issues, the buyer may be notified within the GUI of the design application 127. It should be appreciated that by presenting the design options in a way that is customized to each homebuyer, the system is able to increase both customer satisfaction by offering unique styles and builder profit margin by ensuring that more profit-bearing options are viewed.

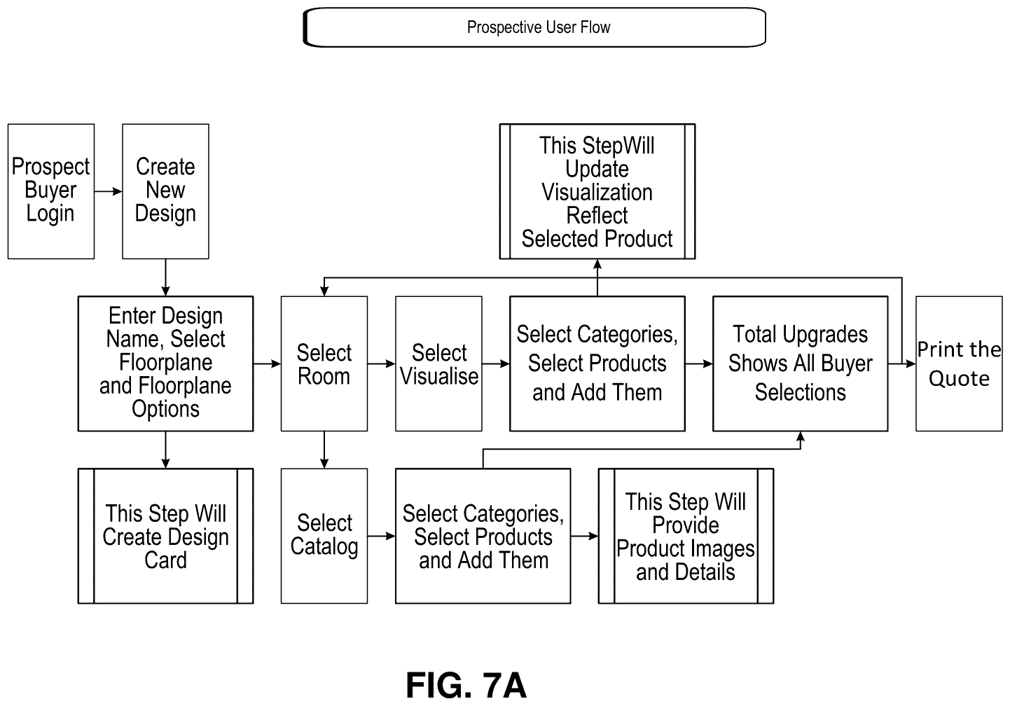

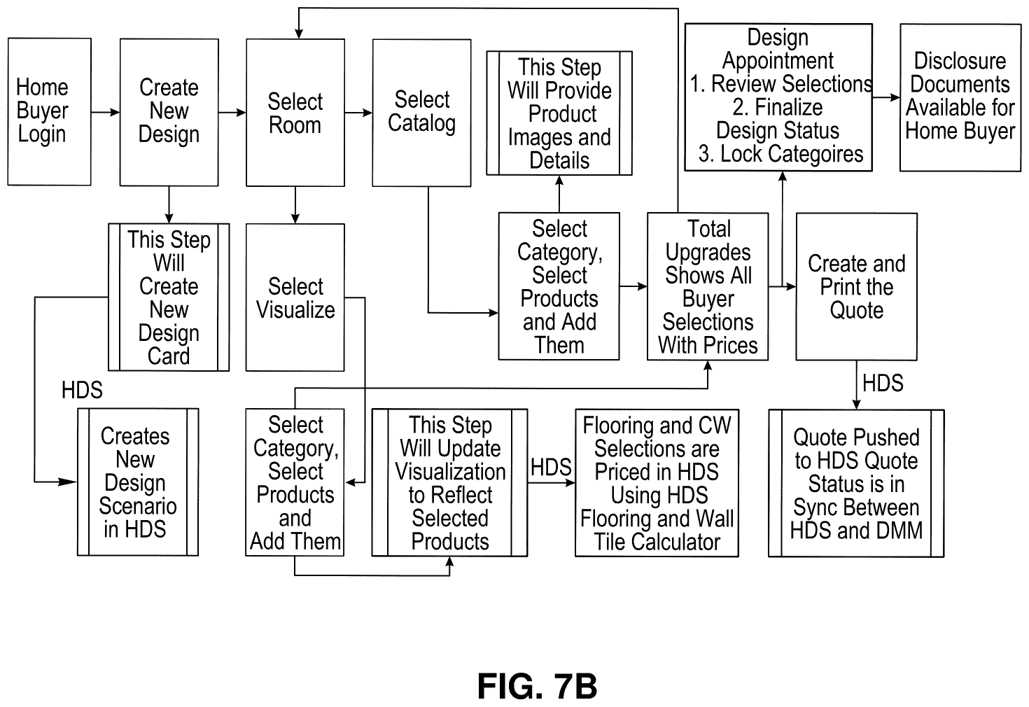

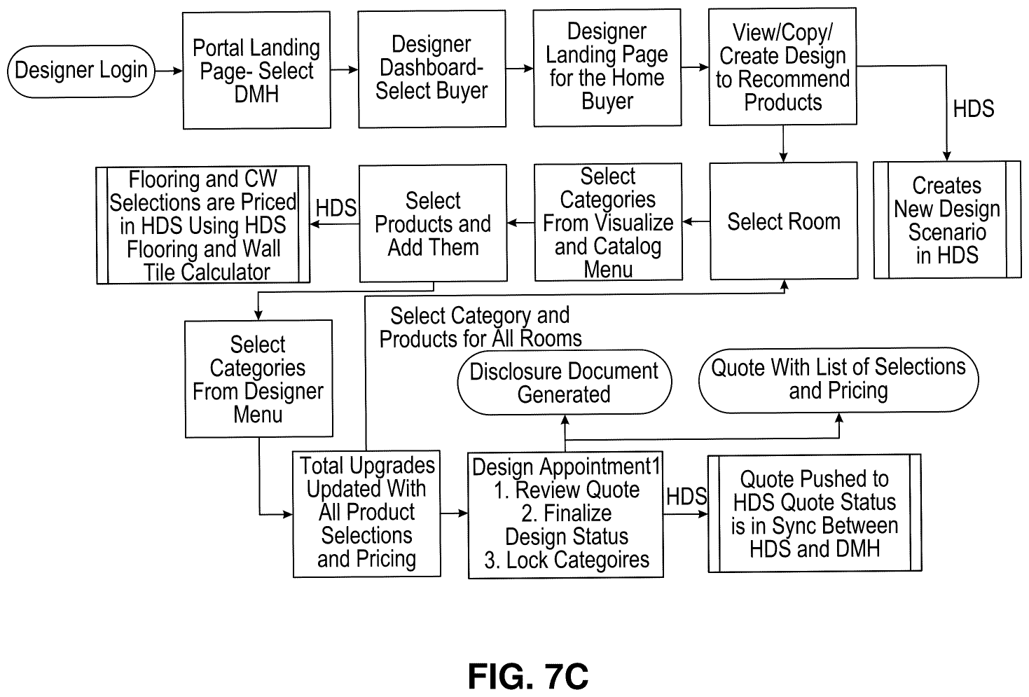

As the buyer makes the selection, the price is updated in real-time along with the visual confirmation of the selection. In particular, as alluded to earlier, images corresponding to selected design are generated by the gaming engine based on the data in the product catalog. These images are used to generate an updated visualization of the space. The buyer may have the ability to view all the upgrades within a space or by category. Once the selections are finalized, the buyer may be able to lock these selections and finalize the design status. For example, FIGS. 7A-7B illustrate example workflow schematics of steps taken by a prospective buyer and homebuyer, respectively, during a customization process. Similarly, designer user may assist the homebuyer user by taking steps illustrated in FIG. 7C. For example, designer user may create new design scenarios which include specifying design options that the homebuyer may be more likely to be satisfied with.

Once the selections are finalized, the hardware processor 104 may execute instruction 124 to generate a final quote for the entire project. It should be appreciated that the generation of the final quote will eliminate error and misunderstanding around selections, as there is not an employee putting together the purchase order. In some embodiments, the buyer user will be prompted to approve and/or finalize the order to further assure accuracy.

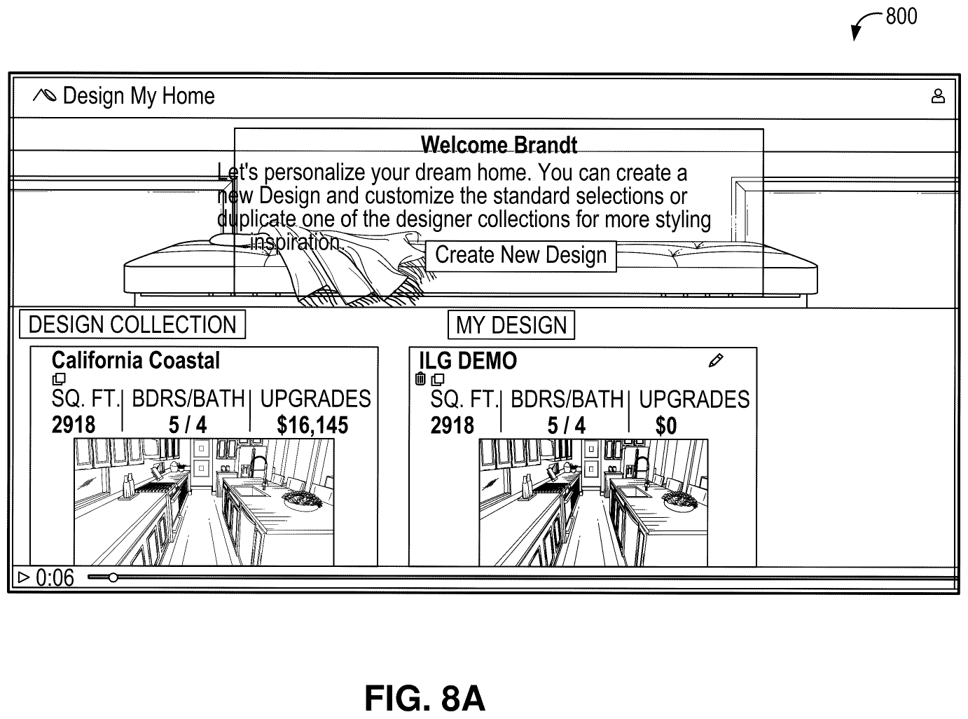

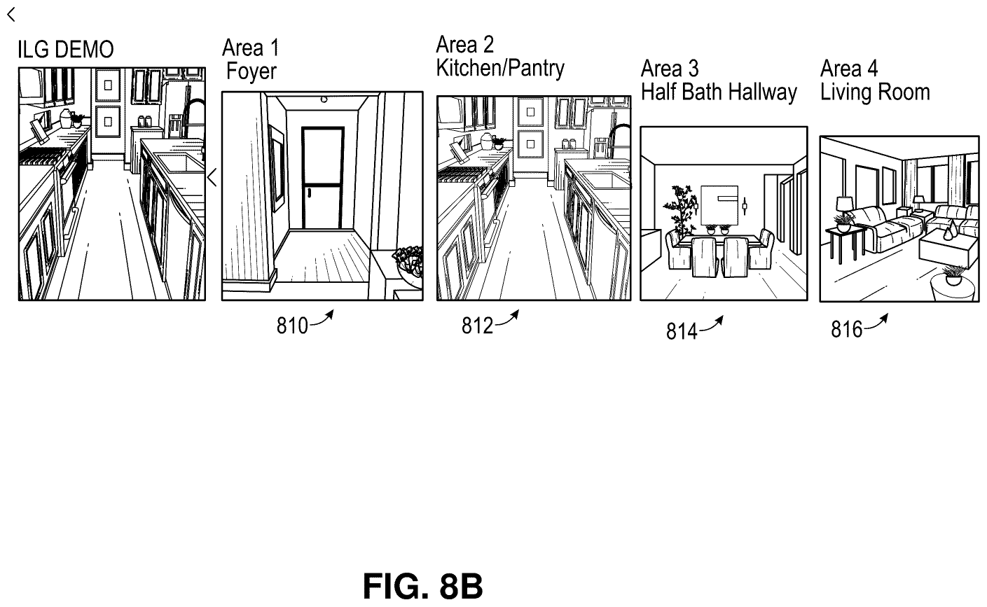

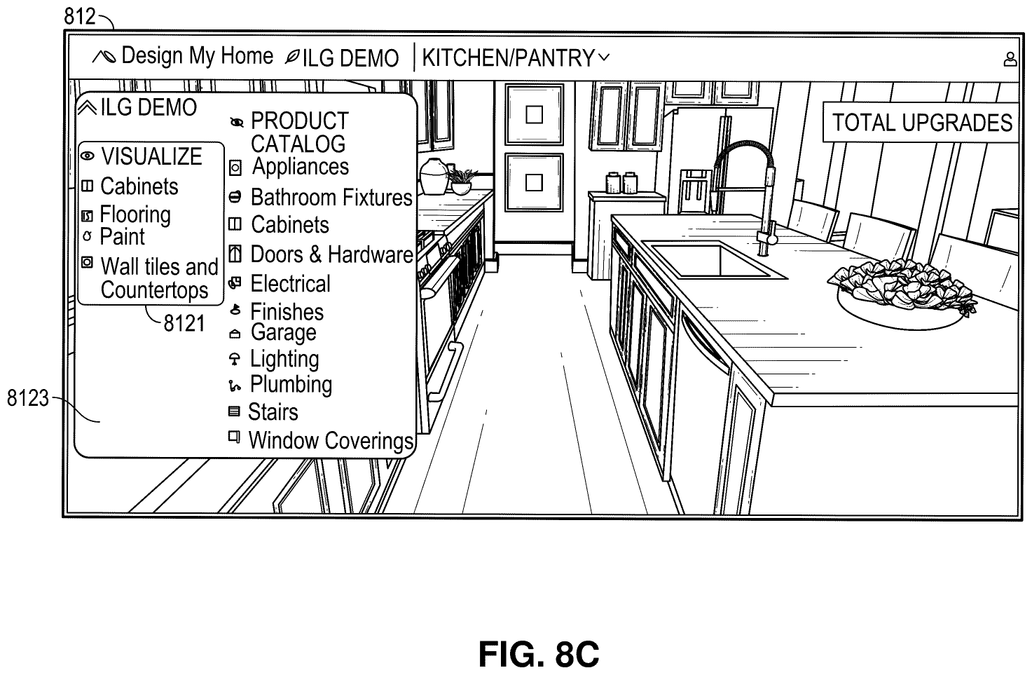

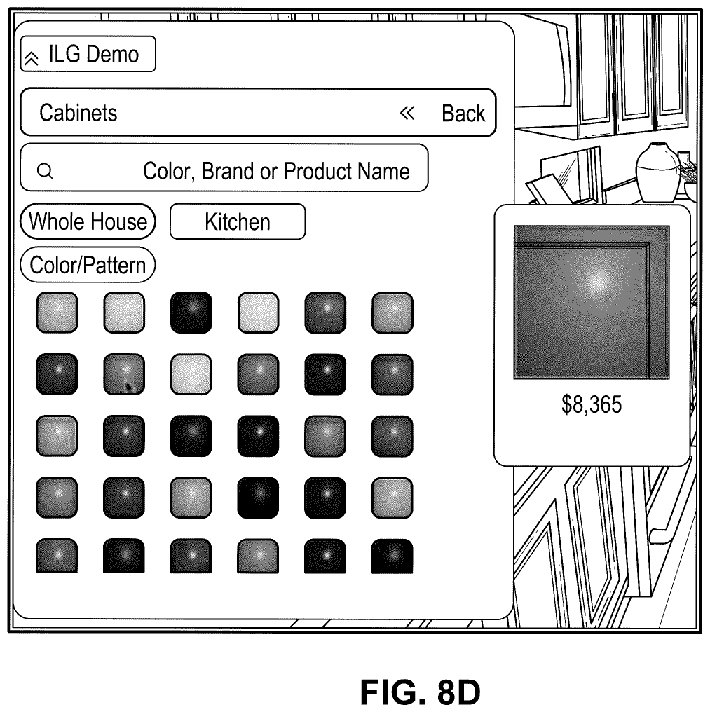

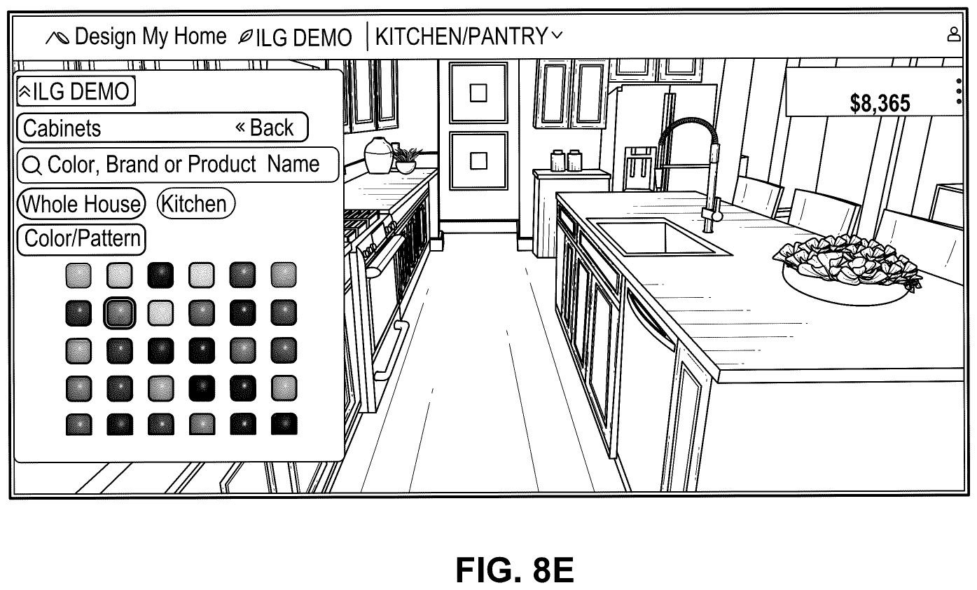

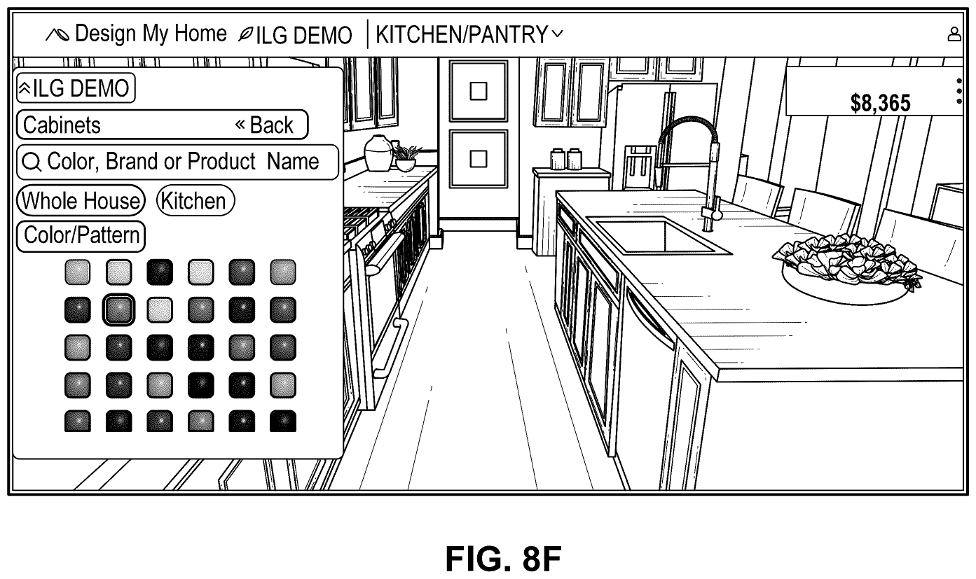

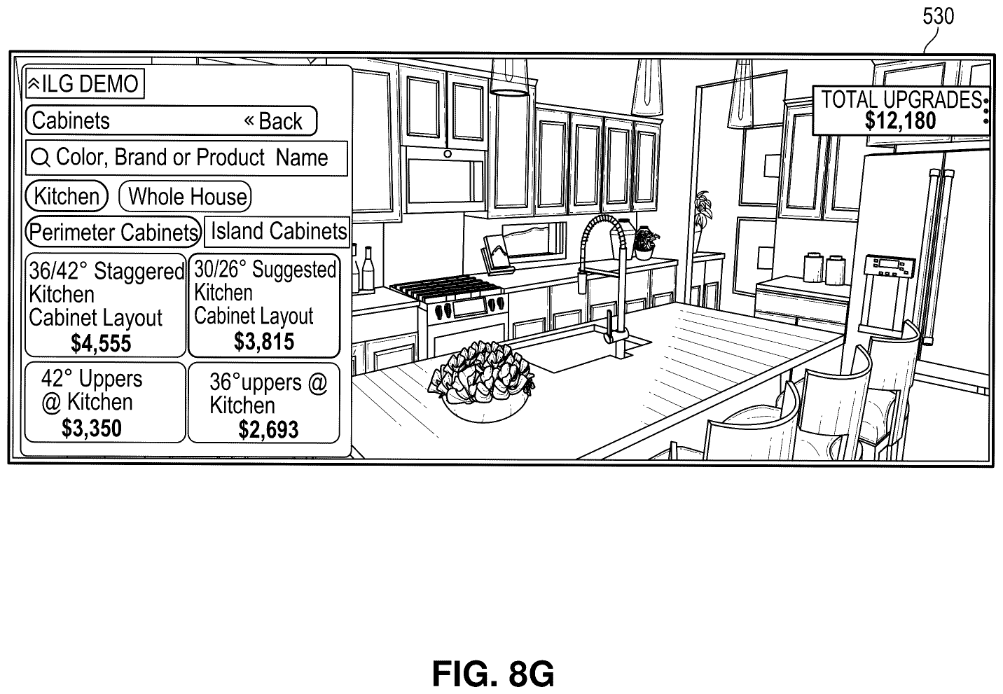

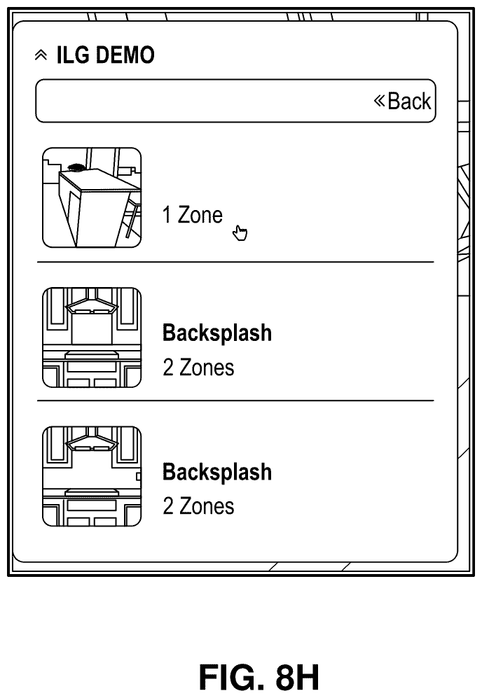

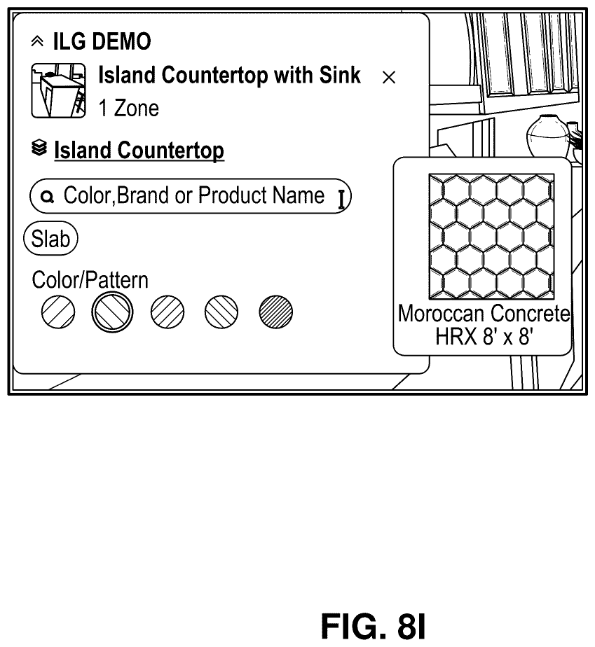

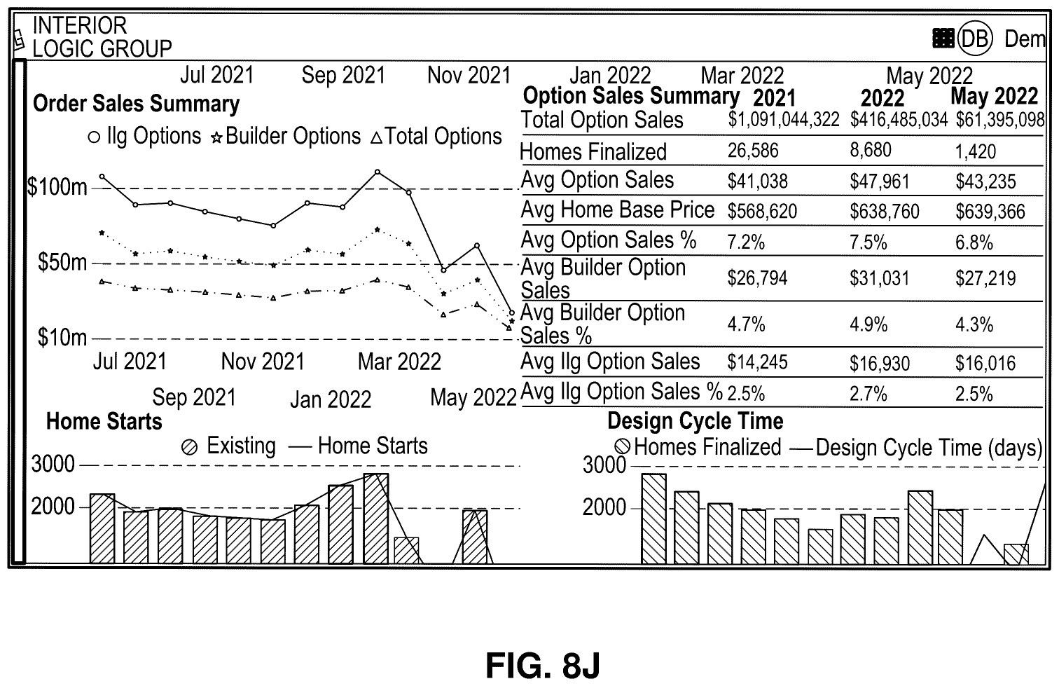

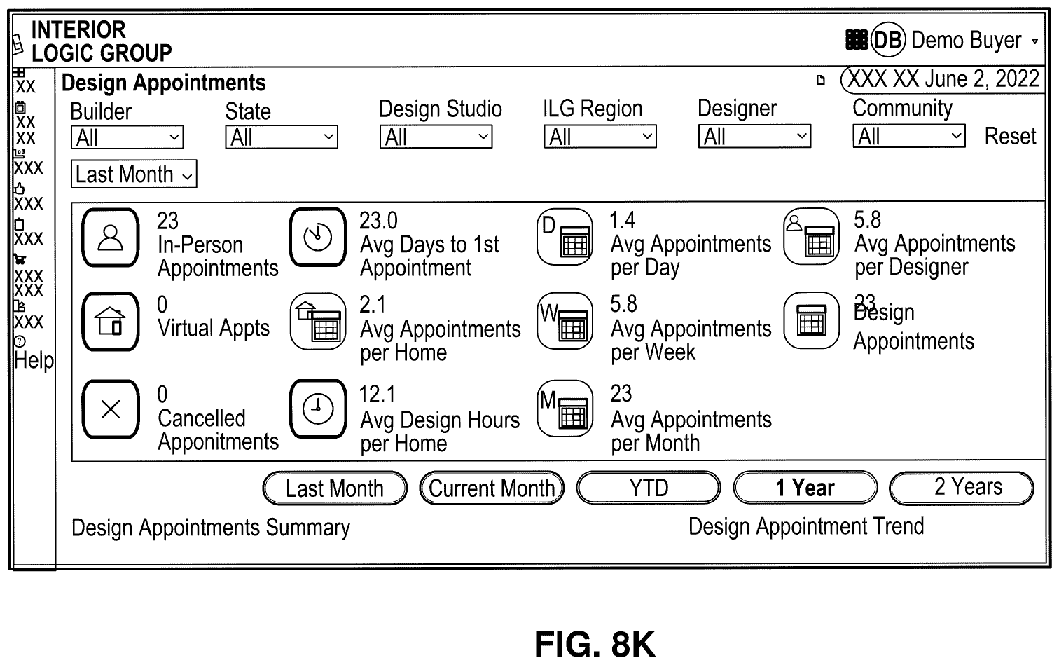

The various examples provided in FIGS. 8A-8I illustrate how a buyer can select one or more design options from a catalog of options that alter the baseline design. Each room or space will have its own associated list of customization options that relate to interior or exterior features of the home. For example, the design options may include appliances, bathroom fixtures, cabinets, doors and hardware, electrical fixtures, finishes, and plumbing, and so on. Moreover, the design options can further include features that that were not present in the baseline model. For example, two sinks instead of one, or a light fixture previously without one.

One exemplary home design process will now be described. This particular example will illustrate one manner of customizing a new construction home, although it is understood that it may similarly apply to any other buildings (e.g., offices, retail spaces, gyms) or other project pertaining to the existing home remolding industry (single family homes, cluster homes, condos, apartments, or others). Additionally, this example will merely describe only one possible workflow, with the understanding that various possible workflows may be used with various steps, order of operations, visual depictions, input/output schemes, etc.

Turning now to FIG. 8A, the user will utilize a graphical user interface (GUI) 800 to enter information into the system 100. The GUI is part of the real-time virtual experience of the design application 127 (illustrated in FIG. 1). In one example, the GUI 800 may be presented upon the touchscreen of the computer input area, and/or may be adapted for the particular display and input being used (e.g., standalone computer, tablet, mobile phone, television, virtual reality, etc.). Additionally, it is noted that the following workflow using the shown GUI 800 may be presented in a template format to help guide the homebuyer through the process and enable only those features permitted by the builder.

Initially, GUI 800 provides an introductory screen that may ask the user to login to an account, or may be done via an anonymous account. Optionally, the system may permit the buyer to directly begin the building design without entering a login account. If the user has a unique login, then the buyer may view recent or past designs that were saved in the system. This permits the buyer to design their home over multiple sessions. The buyer's account and associated design information may be stored within the system, such as within the database 128 or within a server-connected storage (e.g., “cloud” storage) of external resources (e.g., external resources 130 illustrated in FIG. 1).

Upon login (or directly, if no login is used), the buyer can select one of the areas available for customization. In one example, each collection of homes may refer to different builders/manufacturers, locations, home developments, or to different types or styles of available homes. For example, as illustrated in FIG. 8B, areas 810, 812, 814, and 816 representing design of a foyer, kitchen/pantry, half bathroom hallway, and living room, respectively, are available for customization. Each of these areas is a pre-designed base model. Upon selecting an area 812 “kitchen”, the user may select from available menu options 8121 including customization of cabinets, flooring, paint, and wall tiles and countertops, as illustrated in FIG. 8C. Additionally, the buyer may access the product catalog 8123 to view design options related to appliances, bathroom fixtures, cabinets, doors and hardware, electrical fixtures, finishes, and plumbing, etc. FIGS. 8D-8I further illustrate the design option selection process. Note, as the user selects a particular option, the “Total Upgrade” value is updated based on the price associated with the option and the floor plan, as illustrated in FIG. 8G, for example.

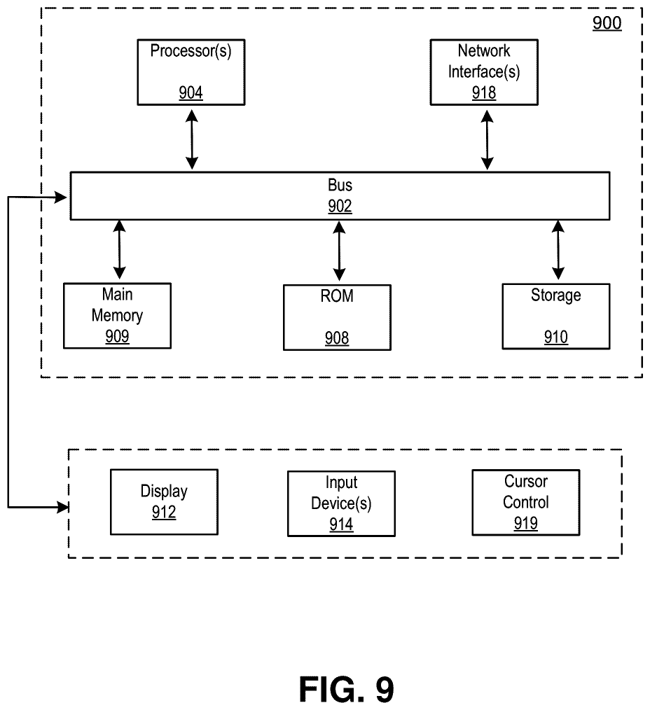

The GUI may have features avail be only to designer users. For example, designers may view analytics associated with the historical design option sales data gathered by the system 100, illustrated in FIG. 8J, and design appointments, illustrated in FIG. 8K.

Where components, logical circuits, or engines of the technology are implemented in whole or in part using software, in one embodiment, these software elements can be implemented to operate with a computing or logical circuit capable of carrying out the functionality described with respect thereto. One such example computing module is shown in FIG. 9. Various embodiments are described in terms of this example computing module 900. After reading this description, it will become apparent to a person skilled in the relevant art how to implement the technology using other logical circuits or architectures.

FIG. 9 illustrates an example computing module 900, an example of which may be a processor/controller resident on a mobile device, or a processor/controller used to operate a payment transaction device, that may be used to implement various features and/or functionality of the systems and methods disclosed in the present disclosure.

As used herein, the term module might describe a given unit of functionality that can be performed in accordance with one or more embodiments of the present application. As used herein, a module might be implemented utilizing any form of hardware, software, or a combination thereof. For example, one or more processors, controllers, ASICs, PLAs, PALs, CPLDs, FPGAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

Where components or modules of the application are implemented in whole or in part using software, in one embodiment, these software elements can be implemented to operate with a computing or processing module capable of carrying out the functionality described with respect thereto. One such example computing module is shown in FIG. 9. Various embodiments are described in terms of this example-computing module 900. After reading this description, it will become apparent to a person skilled in the relevant art how to implement the application using other computing modules or architectures.

Referring now to FIG. 9, computing module 900 may represent, for example, computing or processing capabilities found within desktop, laptop, notebook, and tablet computers; hand-held computing devices (tablets, PDA's, smart phones, cell phones, palmtops, etc.); mainframes, supercomputers, workstations or servers; or any other type of special-purpose or general-purpose computing devices as may be desirable or appropriate for a given application or environment. Computing module 900 might also represent computing capabilities embedded within or otherwise available to a given device. For example, a computing module might be found in other electronic devices such as, for example, digital cameras, navigation systems, cellular telephones, portable computing devices, modems, routers, WAPs, terminals and other electronic devices that might include some form of processing capability.

Computing module 900 might include, for example, one or more processors, controllers, control modules, or other processing devices, such as a processor 904. Processor 904 might be implemented using a general-purpose or special-purpose processing engine such as, for example, a microprocessor, controller, or other control logic. In the illustrated example, processor 904 is connected to a bus 902, although any communication medium can be used to facilitate interaction with other components of computing module 900 or to communicate externally. The bus 902 may also be connected to other components such as a display 912, input devices 914, or cursor control 919 to help facilitate interaction and communications between the processor and/or other components of the computing module 900.

Computing module 900 might also include one or more memory modules, simply referred to herein as main memory 909. For example, preferably random-access memory (RAM) or other dynamic memory might be used for storing information and instructions to be executed by processor 904. Main memory 909 might also be used for storing temporary variables or other intermediate information during execution of instructions to be executed by processor 904. Computing module 900 might likewise include a read only memory (“ROM”) 908 or other static storage device 910 coupled to bus 902 for storing static information and instructions for processor 904.

Computing module 900 might also include one or more various forms of information storage devices 910, which might include, for example, a media drive and a storage unit interface. The media drive might include a drive or other mechanism to support fixed or removable storage media. For example, a hard disk drive, a floppy disk drive, a magnetic tape drive, an optical disk drive, a CD or DVD drive (R or RW), or other removable or fixed media drive might be provided. Accordingly, storage media might include, for example, a hard disk, a floppy disk, magnetic tape, cartridge, optical disk, a CD or DVD, or other fixed or removable medium that is read by, written to or accessed by media drive. As these examples illustrate, the storage media can include a computer usable storage medium having stored therein computer software or data.

In alternative embodiments, information storage devices 910 might include other similar instrumentalities for allowing computer programs or other instructions or data to be loaded into computing module 900. Such instrumentalities might include, for example, a fixed or removable storage unit and a storage unit interface. Examples of such storage units and storage unit interfaces can include a program cartridge and cartridge interface, a removable memory (for example, a flash memory or other removable memory module) and memory slot, a PCMCIA slot and card, and other fixed or removable storage units and interfaces that allow software and data to be transferred from the storage unit to computing module 900.

Computing module 900 might also include a communications interface or network interface(s) 918. Communications or network interface(s) interface 918 might be used to allow software and data to be transferred between computing module 900 and external devices. Examples of communications interface or network interface(s) 918 might include a modem or softmodem, a network interface (such as an Ethernet, network interface card, WiMedia, IEEE 802.XX or other interface), a communications port (such as for example, a USB port, IR port, RS232 port Bluetooth® interface, or other port), or other communications interface. Software and data transferred via communications or network interface(s) 918 might typically be carried on signals, which can be electronic, electromagnetic (which includes optical) or other signals capable of being exchanged by a given communications interface. These signals might be provided to communications interface 918 via a channel. This channel might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to transitory or non-transitory media such as, for example, memory 909, ROM 908, and storage unit interface 910. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing module 900 to perform features or functions of the present application as discussed herein.

Various embodiments have been described with reference to specific exemplary features thereof. It will, however, be evident that various modifications and changes may be made thereto without departing from the broader spirit and scope of the various embodiments as set forth in the appended claims. The specification and figures are, accordingly, to be regarded in an illustrative rather than a restrictive sense.

Although described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the present application, whether or not such embodiments are described and whether or not such features are presented as being a part of a described embodiment. Thus, the breadth and scope of the present application should not be limited by any of the above-described exemplary embodiments.

Terms and phrases used in the present application, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A computer-implement method for processing user input in a three-dimensional virtual model, comprising:
generating a three-dimensional (“3D”) virtual model representing three-dimensional (“3D”) geometries of a space based on a plurality of three-dimensional (“3D”) images of the space;
obtaining, from a user computing device, a user input specifying a design option for a design element located with the space;
updating the 3D virtual model by displaying a modified 3D virtual model, wherein the modified 3D virtual model comprises an image of the design element having the specified design option;
generating an upgrade price for the design element by obtaining pricing data for the design element in the specified design option; and
updating a total price associated with the space based on the generated upgrade price of the design element.

2. The method of claim 1, wherein the space comprises a room in a residential home.

3. The method of claim 1, wherein the design element comprises: an appliance, a bathroom fixture, a cabinet, a door, a hardware element, an electrical fixture, a finish, or a plumbing fixture.

4. The method of claim 1, wherein the design option for the design element comprises: a color, a material, a model, or a manufacturer.

5. The method of claim 2, wherein the 3D virtual model representing the 3D geometries of the space is generated based on a set of dimensions corresponding to a floor plan of the room in the residential home, wherein the floor plan is obtained from a builder computing device.

6. The method of claim 5, wherein the design option for the space element is specified by a selection from a menu; and wherein the menu is generated based on a design model of the floor plan of the residential home.

7. The method of claim 1, wherein the image of the design element in the specified design option is generated based on product data catalog data obtained from a builder computing device.

8. The method of claim 1, wherein the upgrade price for the design element is configured to replace a price associated with the design element without the specified design option.

9. The method of claim 1, further comprising:
obtaining, from the user computing device, a user input specifying an additional design element and a design option for the additional design element located with the space;
updating the 3D virtual model by displaying a modified 3D virtual model, wherein the modified 3D virtual model comprises an image of the additional design element in the specified design option;
generating an upgrade price for the additional design element by obtaining pricing data for the additional design element in the specified design option; and
updating the total price associated with the space based on the generated upgrade price of the additional design element.

10. A system comprising:
one or more computing processors; and
a machine readable storage medium storing instructions that, when executed by the one or more processors, cause the system to:
generate a three-dimensional (“3D”) virtual model representing three-dimensional (“3D”) geometries of a space based on a plurality of three-dimensional (“3D”) images of the space;
obtain, from a user computing device, a user input specifying a design option for a design element located with the space;
update the 3D virtual model by displaying a modified 3D virtual model, wherein the modified 3D virtual model comprises an image of the design element having the specified design option;
generate an upgrade price for the design element by obtaining pricing data for the design element in the specified design option; and
update a total price associated with the space based on the generated upgrade price of the design element.

11. The system of claim 10, wherein the space comprises a room in a residential home.

12. The system of claim 10, wherein the design element comprises: an appliance, a bathroom fixture, a cabinet, a door, a hardware element, an electrical fixture, a finish, or a plumbing fixture.

13. The system of claim 10, wherein the design option for the design element comprises: a color, a material, a model, or a manufacturer.

14. The system of claim 11, wherein the 3D virtual model representing the 3D geometries of the space is generated based on a set of dimensions corresponding to a floor plan of the room in the residential home, wherein the floor plan is obtained from a builder computing device.

15. The system of claim 14, wherein the design option for the space element is specified by a selection from a menu; and wherein the menu is generated based on a design model of the floor plan of the residential home.

16. The system of claim 10, wherein the image of the design element in the specified design option is generated based on product data catalog data obtained from a builder computing device.

17. The system of claim 10, wherein the upgrade price for the design element is configured to replace a price associated with the design element without the specified design option.

18. The system of claim 10, wherein the machine-readable storage medium storing instructions that, when executed by the one or more processors, further cause the system to:
obtain, from the user computing device, a user input specifying an additional design element and a design option for the additional design element located with the space;
update the 3D virtual model by displaying a modified 3D virtual model, wherein the modified 3D virtual model comprises an image of the additional design element in the specified design option;
generate an upgrade price for the additional design element by obtaining pricing data for the additional design element in the specified design option; and
update the total price associated with the space based on the generated upgrade price of the additional design element.

19. A non-transitory computer-readable medium storing computer-readable instructions for generating a three-dimensional virtual model, which when executed by one or more computing devices, cause at least one of the one or more computing devices to:
obtaining, from a builder computing device, a product catalog file specifying information on design options associated with design elements, and a floor plan file specifying information about a space in a building;
parsing the product catalog file to extract design raw data associated with the information on default design options for the design elements, and parsing the floor plan file to extract space raw data associated with the information about the space in the building, wherein the extracted design raw data and space raw data is uploaded to a datastore; and
generating a three-dimensional (“3D”) virtual model representing three-dimensional geometries of the space with design elements based on extracted space raw data and design raw data.

20. The non-transitory computer readable storage medium of claim 19, wherein generating the 3D virtual model comprises generating a plurality of three-dimensional images of the space based on the extracted space raw data from the floor plan file.
